(19) United States
(12) Patent Application Publication
(10) Pub. No.: US 2006/0170996 A1
(43) Pub. Date: Aug. 3, 2006

(54) Color control of a web printing press utilizing intra-image color measurements

(76) Inventors: Steven Headley, Arlington, TX (US); David Brydges, Vaxholm (SE)

Correspondence Address: STALLMAN & POLLOCK LLP, 353 SACRAMENTO STREET, SUITE 2200, SAN FRANCISCO, CA, 94111, US

(21) Appl. No.: 11/338,966

(22) Filed: Jan. 25, 2006

Related U.S. Application Data
(60) Provisional application No. 60/649,212, filed on Feb. 2, 2005.

(51) Int. Cl. G03F 3/08

(52) U.S. Cl. 358/518

(57) ABSTRACT

Accurate on-line color control for a printing press can be obtained using intra-image color control. A concurrent spectrophotometer and imaging system can capture spectral reflectance data from predetermined measurement areas for each ink key zone of the press. The spectral reflectance data can be compared to target reflectance values in the same standard color space, and a determination can be made as to whether the differences between the measured and target values exceed predetermined tolerances. If the differences exceed these tolerances, a necessary adjustment to the appropriate ink key can be calculated to bring the color differences back to within tolerance. This approach is particularly beneficial in web offset printing, where the printed image is constantly moving and the press conditions are particularly variable.

### CLAIM OF PRIORITY

This application claims the benefit of and priority to U.S. Provisional Patent Application No. 60/649,212, filed Feb. 2, 2005, which is hereby incorporated by reference.

### TECHNICAL FIELD OF THE INVENTION

The present invention relates to on-line color control in printing presses and, in particular, to the utilization of intra-image color measurements for color control in web offset printing.

### BACKGROUND

Accurate color control of printing systems such as web-offset printing presses requires that color deviations between established color targets and corresponding areas in subsequently printed images be kept within established color tolerances. When colors deviate beyond these tolerances, inking adjustments in the form of solid ink density or ink layer thickness corrections are made to reduce the color deviation such that the color difference is again within tolerance.

For many years, common practice was for a press operator to visually monitor the printed images and adjust the flow of ink into the press until a visual match was achieved between the target and the printed image. A pre-press proof or previously printed “Color OK” sheet was typically used as the aim or target condition. Due to the inherent variation in color vision, both within individuals over time and between different individuals, this procedure is subject to large variability and is relatively time consuming. Instrumental color control offers an alternative for process color control that is more repeatable, accurate and efficient.

Densitometry has been the main measurement method within the graphic arts industry for measuring and controlling the primary inks and related attributes in process color printing, as a densitometer is well-suited for measurements pertaining to the relative strength of a process color solid ink film. Controlling using measurement of solids is recognized by the industry to be somewhat flawed, however, as an inference is required as to how these solid colors will affect the tints (screened image elements consisting of various dots of ink), which in turn requires an inference as to how these tints will affect the resulting image. Subsequent systems relied upon patches of a single color comprised of different tone values (sizes of ink dots) to get a better idea of how the ink behaves in an actual image, where the colors are not typically solid regions of one of the three or four primary colors. These approaches still require an inference as to how the tints will actually affect the image when overlaid at various levels and locations.

More recent systems measure a color bar that allows for color control using at least one gray patch in the bar, which can give an indication of the three or four primary colors (e.g., cyan, magenta, yellow, and sometimes black) used to create that gray, the respective tone values, and how those levels work when overlaid. For applications such as newspapers where there are no to-be-discarded regions in which to include a color bar, a continuous gray color bar can be included in the image area of the newspaper where the bar will be the least distracting. These bars often take the form of a header or footer bar that looks to be part of the design of the page. These bars allow for control directly from a single gray measurement, instead of at least four or five separate measurements. For instance, a single measurement of a three-color gray bar gives an indication of the tone values for each of the three component colors (e.g., a yellow tint, printed on top of a magenta tint, printed on top of a cyan tint). This approach still requires an additional area (the gray bar), is indicative of only one area on the page, and requires an inference as to how the various other colors will appear. Measuring on the color bar still requires an inference as to what is going on in the image.

As mentioned above, measurements for color control are most commonly made on color control bars that contain a variety of test elements, each element providing information on various print quality attributes. Test elements (usually called swatches or patches) commonly found in color bars include solids (100% area coverage), halftone tints of various area coverage for each of the primary inks (black, cyan, magenta and yellow), and two and three-color overprints of the primary chromatic inks (cyan, magenta and yellow). Although color control based on color bar measurements provides a high level of print quality, it would be desirable to obtain a high level of print quality without the need for these additional bars, which are not aesthetically pleasing.

Color control methods using measurements on solid (100% area coverage) swatches provide a direct means of control, as solid ink density (SID) is the only variable that can be adjusted directly in real time on typical existing systems, but are limited because several important attributes related to image quality, such as tone value increase (dot gain) and trapping (how well the component process ink films lay down on top of each other), are not taken into consideration, and can impact image reproduction in addition to changes in solid ink density. As a result, when performing control of color based on solid ink density alone, the appearance of the object being printed may deviate significantly from the established “Color OK”, although the solid ink density measurements indicate otherwise. It is, therefore, important to select swatches and/or color bars that either have maximum sensitivity to changes in the important print quality attributes previously mentioned, or that are a visually significant aspect of the print. Additionally, a minimum number of swatches should be used in order to reduce the number of color measurements necessary for control purposes.

Color control applied to the control of a web printing press must maintain an acceptable match not only between an established color target location and that same location in a printed image, but also between the target and each subsequently printed image on the moving web. Therefore, a color measurement instrument is needed that is capable of describing the color of objects in approximate visual terms. Instruments such as spectrophotometers can be used that report both densitometric and colorimetric data calculated according to standard procedures. It can be advantageous to use a spectral engine instead of a densitometer, as a spectral engine can acquire measurement data across the entire reflected spectrum of an image to accomplish complete image control. Methods for performing color control on printing presses using a spectrophotometer are described in U.S. Pat. Nos. 4,975,862, 5,182,721 and 6,041,708. These patents, however, describe methods for controlling the printing press with colorimetric coordinates, which are obtained from spectral reflectance data rather than using the spectral reflectance data directly. U.S. Pat. No. 6,802,254 describes converting spectral reflectance values to colorimetric density values from which a colorimetric density difference is established, which then is used to determine an ink correction value. U.S. Pat. No. 6,564,714 describes using the spectral reflectance data directly to determine a spectral reflectance difference, which then can be related to solid ink density or ink layer thickness differences for use in color control. All of these patents are hereby incorporated by reference to provide background information relating to the present invention.

Colorimetric models that are typically used with swatches and/or color bars provide less accurate control as compared to spectral models, primarily in situations where the spectral reflectance difference between two ink settings cannot be described by a single constant or multiplication factor. Additionally, off-line methods of calculating the parameters of the matrix relating solid ink density or ink layer thickness differences to spectral reflectance differences are not accurate enough for use in a commercial color control system. Such methods only represent the state of the system at one point in time. Dynamic methods of calculating the matrix on-line in real-time during the press run would greatly improve the effectiveness and accuracy of the control method.

Control of any system requires knowledge of the relationship between the input variable(s) and the output variable(s). In printing, although there are many options for input variables, the main press control or output variable influencing the visual impression of the printed image is the inking system, which modulates the flow of ink into the press. By varying the volume of ink flowing into the press, the thickness of the ink layer deposited onto the substrate will vary, thereby influencing the color of the print.

Control of the inking in most printing presses is carried out on a zone-by-zone basis, where each zone corresponds to a width (e.g., 32 mm) across the image as shown in FIG. 1. For an exemplary page layout 100, there are a number of zones 102 that each correspond to an ink key of the press, with the elongated ink zone having its major axis parallel to the print direction, or the direction of the moving web. Within each ink zone 102, the corresponding ink key is used to adjust the amount of ink flowing into this region of the press, which in turn will influence the color of the image(s) located within the specific zone, as well as any neighboring zones. The ink keys can be adjusted manually as in old systems, or can be controlled by a servo motor or other drive mechanism in an automated ink control system. In this manner, the inking is adjusted to produce the desired colors. It is important for accurate color control to select proper test regions in the printed image that are sensitive to variations in important print quality attributes, and that are representative of the printed area as a whole.

A measurement instrument such as a spectrophotometer detects the light reflected from a measurement location to determine the color of a test area. An exemplary spectrophotometer utilizes a spectral grating and an array of sensors to collect and analyze reflected light. The output is a set of spectral reflectance values that describe the relative light-reflecting characteristics of an object over the visible spectrum, such as at some small constant-width wavelength interval. The reflectance values can be obtained by calculating the spectral reflectance factor, which typically is a ratio of the amount of light reflected from the sample relative to that of a standard reference material similarly illuminated, wavelength by wavelength, across the visible spectrum. Spectrophotometers have the added advantage that the spectral reflectance values can be converted to both colorimetric and densitometric representations according to standard calculations. The term “density” as used herein refers to densities calculated according to standard practice as documented in, for example, American National Standard for Photography (Sensitometry)—Density Measurements—Spectral Conditions. ANSI/ISO 5/3-1995, ANSI PH2.18-1985, New York: American National Standards Institute. The term “colorimetric” is used to refer to colorimetric coordinates calculated according to standard practice as documented in, CGATS.5-2003 Graphic technology—Spectral measurement and colorimetric computation for graphic arts images.

While it would be desirable to do away with the color bars and swatches and use intra-image measurements for color control, a number of obstacles prevent this from occurring in the marketplace. First, it is necessary to use a camera or other imaging device to locate on each page the locations to be measured, which can be difficult on presses such as web printing presses where the image is printed to a continuous roll of substrate (a web) moving through the machine at a rate of up to 3,500 fpm. It also is necessary to take measurements at those locations, which requires ensuring that the area being measured is the same as the area that was located by the imaging device. Since a high-speed digital camera cannot provide true color measurements, this would require another instrument to take the measurements, and would require tight control over the relative positions and timing of the instrument and imaging device. This can be difficult on a press that might vibrate heavily during operation at high speeds and/or loads, and that might exhibit slight variations in press or substrate speed over time. It also is difficult to determine how press conditions might vary over time, such that making online, real-time corrections can be imprecise due to over- or under-shooting adjustments as a result of these variations in print conditions.

### BRIEF DESCRIPTION OF THE DRAWINGS

FIG. 1 illustrates the layout of a printed page and the ink zones used to print that page.

FIG. 2 is a flow chart illustrating a method of utilizing intra-image color measurements for color control in a web offset printing process in accordance with the present invention.

FIG. 3 is a diagram of a system that can be used for intra-image control of a printing press using a method such as that of FIG. 2.

### DETAILED DESCRIPTION

Systems and methods in accordance with various embodiments of the present invention can perform on-line measurements in the image area of a printed sheet, such as a moving web, without the presence of a printed colorbar. Such systems can determine measurement locations and acquire measurement data from these locations at high speeds, thus enabling concurrent color measurement and imaging. Such systems also can utilize a combination of hardware and software approaches to obtain color information and adjust the color appearance of the print using various color control algorithms and methodologies. Embodiments of the present invention can provide for color control of printing presses through direct use of spectral reflectance data. Spectral reflectance differences between a target and test area can be determined and used to calculate solid ink density or ink layer thickness corrections for use in controlling a printing press. Various methods described herein can convert a spectral reflectance difference directly into either solid ink density or ink layer thickness corrections, such as through the use of at least one linear equation employing an empirically derived transformation matrix that can be calculated on-line. These methods can be applicable to the control of process and/or non-process (PMS or special) colors. Data can be obtained from spectral measurements using image areas within the printed product, without the need for color bar swatches. Color bar swatches, however, can be used as an additional indicator of solid and/or tone value levels for each ink being monitored, if desired. Of course, any person skilled in the art will appreciate that any reference in this document to a “printed image” or to “in-image” measurements is directed to that portion of the printed product that is considered “work product” or “salable product:, and typically does not include the colorbar portion of the printed work.

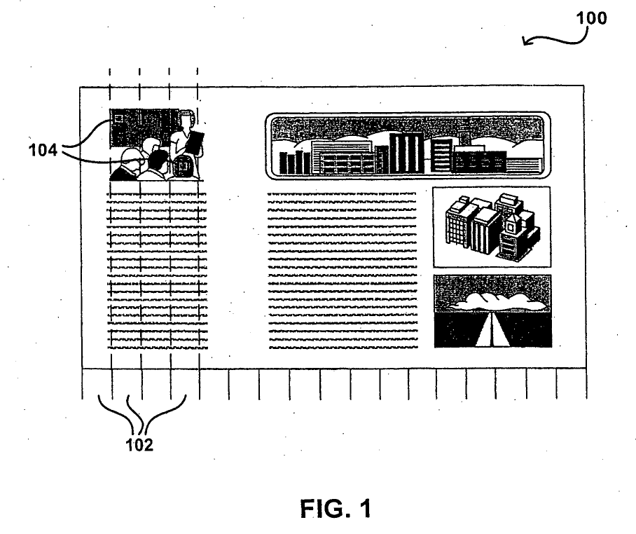

As discussed above, FIG. 1 shows a plurality of ink key zones 102 that each can be monitored to ensure proper color reproduction. For each ink key zone, at least one measurement area 104 can be selected for color analysis. Methods for selecting and analyzing these measurement areas are discussed in greater detail below.

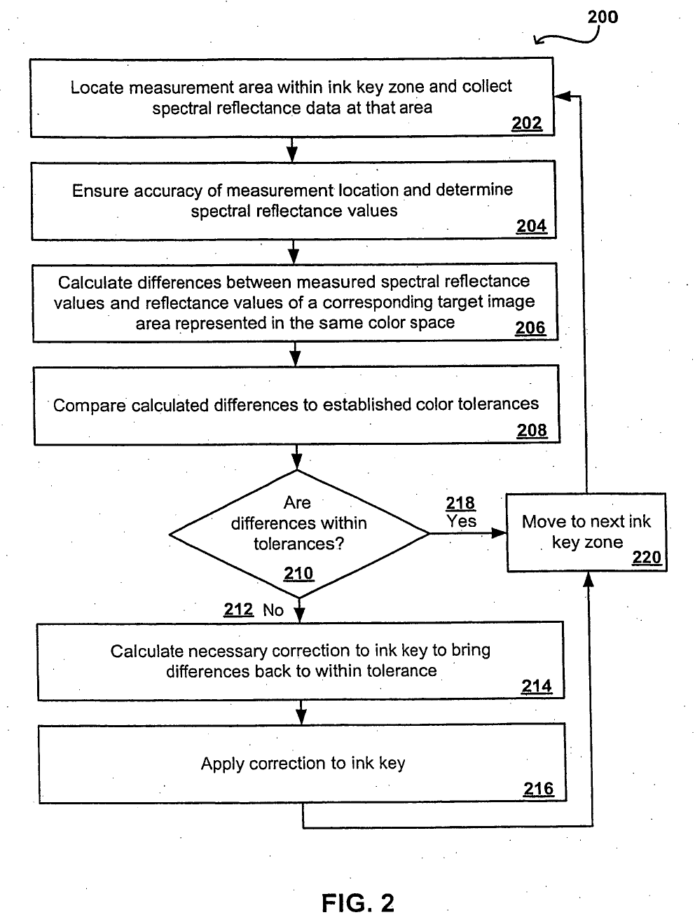

An exemplary process 200 for measuring the spectral reflectance of an in-image area using a spectrophotometer is shown in the flowchart of FIG. 2. The method is described with respect to a single ink key and single measurement area, with steps that can be repeated (concurrently or at different times) for additional ink keys in a printing system. For a given ink key zone, a predetermined measurement area can be located such that an image and spectral reflectance data can be captured from that measurement area using a concurrent imaging and spectral reflectance measurement tool 202. The captured data from the imaging system can be analyzed to ensure the accuracy of the measurement area, using the image data, and to determine the spectral reflectance values, using the spectral reflectance measurement data 204. The measured spectral reflectance data then can be compared to the target reflectance data represented in the same color space, such that the differences can be calculated 206.

To determine whether an inking correction is required, the color differences can be compared to established color tolerances 208 for any of the measurement locations of the target in question. Color tolerances for a target image area can be established prior to printing, and can be based on industry standards, plant-specific printing standards, or any other appropriate standards. A determination then can be made as to whether the color is out of tolerance for the selected standard and a correction needs to be made 210. A spectral reflectance analysis for a given measurement area might calculate the reflectance value for 40 points across the visible spectrum, for example, such that each of those 40 points can be compared to the corresponding points in the spectrum for the target image location. Determining whether a correction needs to be made can be performed in any of a number of ways. For example, the color can be determined to need adjustment if any one of the 40 point differences is out of tolerance, if certain of those differences are out of tolerance, if a number of those differences are out of tolerance, if all the differences are out of tolerance, or if an average difference is out of tolerance. There also can be different tolerances established for each point.

If the reflectance differences are out of tolerance 212, a correction can be calculated that, when adjusting the ink keys by the calculated amount, should bring those values back to within tolerance 214. This calculation can take into account the difference between the printed image and the target image, as well as the characteristics of the press, in order to make the necessary adjustments to the press to go back to within tolerance. For instance, if it is determined that the printed image has 5% too little cyan based on spectral reflectance data, a calculation can be done to determine how much the cyan ink key for the appropriate ink key zone must be adjusted. Spectral differences can be converted directly to solid ink density corrections as described, for example, in U.S. Pat. No. 6,564,714, which is hereby incorporated by reference. This correction then can be applied to the appropriate ink key of the printing press 216. If none of the locations are outside a respective defined color difference tolerance 218, then no correction is necessary and the process can be repeated for a different ink key and/or zone 220. In another embodiment, there may be a continual monitoring and adjustment to attempt to keep the color-difference near zero, whereby small adjustments can be made after any measurement, whether or not the difference falls outside a specific difference range or tolerance.

System Architecture and Spectral Engine

An online system that images the measurement location concurrent with the actual measurement data acquisition can be used to achieve the goals and meet the requirements mentioned above, as concurrent measurement and imaging can provide several benefits with regard to intra-image measurement, such as verification of the exact measurement location. This can be particularly important when reading an image on a moving web, due to process conditions as discussed above. Further, acquiring an image on a moving web typically comes with a different set of hardware requirements than is used to measure a color bar. For instance, a color bar can be printed in the same location on each page of the rolling web, such that basic imaging technology can be used to determine whether the bar shifts a little in position, and an analysis can be done at a regular interval and at a relatively stable location. When capturing data at various places throughout the entire image of a page, it can be necessary to not only capture images at several different locations, but to ensure that the instrument is measuring at each proper location within the moving image.

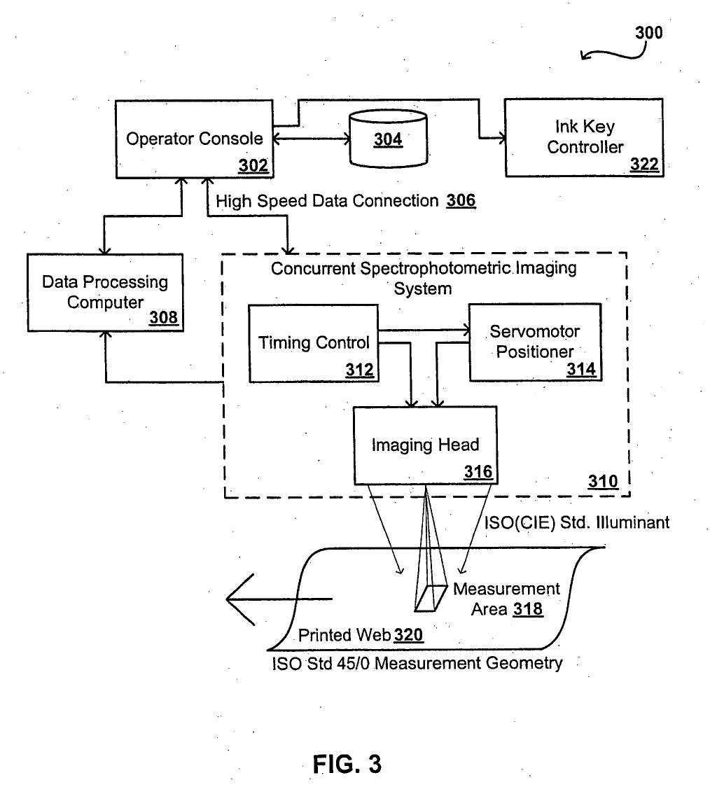

One such system 300 is shown in FIG. 3. In this system, an operator console 302 allows an operator to accomplish any of a number of possible tasks, such as the input of data, monitoring of process parameters, and modification of measurement area selections, for example. The operator console 302 can retrieve data regarding selected measurement areas, color targets, and color tolerances from a database 304 containing that information. The console also can write new color information to the database during the printing process, such as to adjust measurement locations or target values. The operator console can be connected to a spectrophotometric imaging system 310 through a high speed data connection 306 that allows the operator console to activate and control the imaging system 310. The imaging system can include a timing control computer or module for controlling a circumferential position of the imaging head 316, and for providing a lateral position control signal to a servomotor positioner 314. The timing control 312 and servomotor positioner 314 can work together to position the imaging head 316 and control the interval(s) at which the imaging head captures image and spectral reflectance data.

The imaging head can include an ISO standard illuminant capable of illuminating an area of the moving web 320. The head can capture data from a predetermined measurement area 318 on the moving web 320 as directed by the timing control module 312. The image and reflectance data captured by the imaging head can be forwarded to a data processing computer 308 capable of determining whether the proper measurement area was located and calculating the reflectance values for the measurement location. It should be understood that the components shown in the diagram are exemplary, and that a number of variations are possible as would be understood to one of ordinary skill in the art, such as the data processing computer being part of the operator console or imaging system. Once the data processing computer 308 has determined whether the color differences are out of tolerance and/or whether an adjustment needs to be made to the appropriate ink key, a signal can be sent to the operator console and/or ink key controller 322 to make any necessary adjustments. Determinations of tolerances and adjustments are discussed in greater detail below. The physical ink key adjustments can be done manually or automatically, as would be known to one of ordinary skill in the art. Further, the term “ink key” is used generically to refer to any mechanism capable of adjusting the amount (or other appropriate aspect) of ink of a particular color applied to a particular area or “zone” of the to-be-printed material.

One concurrent imaging and measurement system that can be used in accordance with embodiments of the present invention utilizes a device known as a hyperspectral monochrometer, spectrophotometer, or spectrograph. One such hyperspectral monochrometer that can be used in a system in accordance with embodiments of the present invention is a Hyperspec™ VS-25 spectrograph available from Headwall Photonics of Fitchburg, Mass. This device is a compact imaging spectrograph that provides high throughput and compatibility with large-format focal plane array detectors. This spectrograph utilizes holographic diffraction gratings to reduce stray light, as well as high throughput optics to ensure high signal-to-noise ratios. The spectrograph can obtain high-quality imaging over the full extent of an 18 mm tall slit, providing high spatial resolution, with the 12 μm width of the slit providing high spectral resolution. Such a spectrograph can cover a 400-1000 nm wavelength range over a 6.0 mm dispersion with extremely high system efficiency and resolution.

Spectrographs typically have three basic elements: an objective element to gather an image, a dispersive element to split the image into spectral channels, and a detector to capture the resultant images. A frame grabber can be used to build a two-dimensional visual image at each spectral channel, with the wavelength of the spectral channel providing a third dimension. The resultant three-dimensional data array can be viewed as an entire image at any wavelength or as a full spectrum of any individual pixel in the image. A hyperspectral imager can generate a spatial image for each channel, which can result in large data arrays for applications such as moving-web applications where a web of moving substrate of several feet in width can move at thousands of feet per minute. The number of potential spatial channels can be given by the image field of view divided by the spatial resolution, for example. Such a grating spectrophotometer can obtain the spectra for each point in a line simultaneously, avoiding the mixing of spectral signatures in temporally changing scenes. The dispersive implementation by use of grating technology allows the optical system designers to demultiplex discrete wavelengths from a common input source.

Constraints imposed by line scan imaging in one embodiment can require a constant illumination source. A hyperspectral monochrometer can generate a full reflectance spectrum in the associated column pixels for each spatial row pixel. An image can be built during the line scan process that consists of a series of image planes, with each image plane corresponding to a specific spectral wavelength. Generating a measurement can consist of selecting appropriate “target” pixels and using the associated spectral information to generate measurement data. An appreciable benefit of such an approach is the ability to vary the size and shape of the measurement (virtual) aperture by selecting the appropriate number and location(s) of the aperture pixels in the image.

A hyperspectral monochrometer can utilize an area scan CCD array or other appropriate imaging device to capture spatial information in one dimension of the array and spectral information in the other dimension of the array. For each spatial location row pixel, full spectral information can be available in the corresponding column pixels. Such an imaging architecture can operate by line scan imaging. Depending on the image resolution, a large amount of data can be extracted from the imaging device in a limited time frame. An imaging device of this type can reduce the amount of “instantaneous” data that must be manipulated by capturing one line at a time, but requires multiple acquisitions to build up a complete image. Implementation with this type of line scan imaging device can further require an extremely stable and uniform series of “trigger events.” One approach to providing the “trigger events” uses an encoder device with extremely fine resolution. Resolution, in this sense, refers to the resolution of linear distance within a printed sheet on the web. Since line scan imaging devices build an image a line at a time, or are continuously generating an output “profile” of a linear area of the target, stroboscopic illumination is not required, nor is any type of shuttering system typically required. A constant illumination source can be used in this case, but the illumination requirements for this type of imaging system must also meet spectrophotometric standards for reflectance measurements.

A spectrophotometer provides a significant advantage to a standard RGB digital camera, in that the spectrophotometer can provide information over the entire visual spectrum. In contrast, an RGB camera typically only provides three values for each image: a red (R) value, a green (G) value, and a blue (B) value. For a printed color where a critical color component is not at or near one of these RGB values, the camera cannot provide an accurate measure of that color. For companies where a specific color is part of their trade dress, it can be crucial to accurately reproduce a color.

Individual subsystems in a concurrent imaging and measurement approach can utilize independent control and data processing hardware to operate effectively. In one implementation, all image acquisition, image processing, and measurement acquisition is performed within the actual scan head, with the results being communicated to a remote location for further action. In another embodiment the image and measurement acquisition operations are located within the scan head, but the processing of the generated data occurs at a remote computing location. The generated data can be stored local to the processing hardware, in either embodiment, at least on a temporary basis. Large amounts of data can be moved at high speeds, using communication channels capable of providing the necessary bandwidth.

Image Information

One of the basic requirements for a color control system based on intra-image measurements, which typically will not utilize a color bar, is a-priori knowledge of the page layout for selection of a suitable measurement location(s) and the corresponding target values (spectral, colorimetric, or densitometric) within the page. Suitable measurement locations can be defined as those locations that are suitable for both measurement and control purposes. As discussed above, intra-image measurement for color control in web-offset printing has not been commercially available for numerous reasons. Even with a-priori knowledge of the page layout, it is not a trivial task to acquire the necessary types of measurement locations to enable accurate and consistent control of the printing press. It is desirable, however, to provide for color control of a web printing press using intra-image color measurements. When imaging with concurrent measurement, it also can be necessary to select an appropriate resolution, field of view, and working distance for a given image and/or measurement location. The resolution and distance can be determined by factors such as the size and/or density of the printed dots in the image.

The most significant specifications for the format of pre-press data have come from the International Cooperation for Integration of Pre-press, Press and Post-press (CIP3) and the International Cooperation for Integration of Processes in Pre-press, Press and Post-press (CIP4) which has superseded CIP3. The CIP3 organization developed the Print Production Format (PPF), which provides a medium by which the information generated in pre-press can be used by downstream operations such as press and finishing operations. The CIP4 committee has gone a step beyond the PPF and developed the Job Definition Format (JDF) that builds on and extends beyond the capabilities of the PPF by also enabling the integration of commercial and planning applications into the technical workflow. The PPF format essentially handles a sub-set of the information and capabilities that the JDF defines. Of the information that will be available in the CIP file formats, the most useful for intra-image measurement and control is the low-resolution separated images provided by the PPF file. These images will be used to determine measurement locations within the page, and their corresponding target values. The PPF format specifies the minimum requirements for the preview data in terms of spatial and tonal resolution.

The low-resolution preview image files may be generated by the page layout software, the raster image processor (RIP), or the computer to plate system (CTP). The preview image files can contain the contents of the complete sheet as a low-resolution continuous tone image. If only the standard printing colors cyan, magenta, yellow and black are used, it is possible to store the image as a composite CMYK image and or as individual CMYK separations. Preview images also can be provided in the industry standard CIELAB color space.

For accurate control, suitable measurement information about each of the inks within each of the ink key zones where the ink is present can be necessary. Additionally, knowledge of the most desirable measurement locations can be required. For example, locations containing good information on several inks, areas containing colors that are very important for color image reproduction, or areas containing colors that are very sensitive to ink film thickness variations can be desirable for testing. The measurement location selections can be determined from the processed preview image file of the page layout, and can be determined to be the best combination of measurement locations within each ink key to meet the above stated requirement. The selection of primary color measurement locations can be determined from within the system operating software and/or by operator selection. A subset of the determined measurement locations can be used for color control, with the remainder used for color reporting purposes.

When selecting measurement locations for control purposes, it generally is not sufficient to determine that a measurement location contains a specific ink. It can be necessary to determine the tone value of the area of interest. Since color differences can be primarily due to changes in ink film thickness and dot area, tone values can be selected advantageously from a tone region that is sensitive to changes in both ink film thickness and dot area. In general, tones in the ¾tone region (approximately 75% image area coverage) are desired. Additionally, information on solid or near solid density values can be important to ensure that the solid ink density values, which provide contrast in the solid image areas, achieve and maintain an acceptable level of contrast.

As discussed above, locations of targets for measurement reporting can be determined prior to printing by the pre-press department or QC department, and can be modified during printing by the press operator. Locations pre-selected prior to printing, and locations that may be selected by the press operator during printing, may still need to meet certain operating system measurement location requirements. Once the measurement locations of interest are known, the target values for the measurement locations can be determined from the preview image files. In order to determine the target values, knowledge of the expected printing conditions is required. This information can be obtained either from an ICC Color Profile, or from measurement data used to create the color profile. The press operator can modify the target values for the measurement locations during an on-press make-ready process if necessary.

ICC Color Profiles typically are created by measuring a test target that has been printed under specific printing conditions. This measurement data can be used in combination with user-defined conditions, such as in color management software packages, to generate an ICC color profile. Each ICC color profile can consist of several look-up tables. For each of the four rendering intents (Perceptual, Saturation, Relative Colorimetric and Absolute Colorimetric) there are two look-up tables. One is a forward (A to B) table that converts CMYK values to color values, and the other is a reverse (B to A) table that converts color values to CMYK values. To convert the CMYK values from the preview image files to colorimetric values the absolute colorimetric rendering intent, an A to B look-up table will be used.

Image Processing

In order to provide the benefits of concurrent measurement and imaging, complex image processing operations may need to be performed on large amounts of image data in a relatively short period of time. Image operations such as filtering, thresholding, edge detection, segmentation, feature extraction, and pattern matching can be performed to extract valid location data from the captured image. The actual measured location within the acquired image, or within a measured image line profile, can be compared to the desired target location that was determined or specified, then extracted by the measurement target location processes as mentioned above. A tolerance level can be specified for positional errors and an actual measurement location that deviates outside of this tolerance can be used and reported with the actual measured position

An advantage of using spectrophotometry is that the color control method can be based on specific wavelengths of the spectrum. This provides for a very precise control method, as specific points in the spectrum can be selected for monitoring that can be more important, variable, and/or easily distinguished than other wavelengths. Further, different images might require different numbers of points across the spectrum, such that less complex images do not utilize unnecessary processing and analysis. The points across the spectrum, the number of points for a color, and the number of colors analyzed can be selected according to what is known about the print job. The analysis can be customized to the print job to ensure that no more analysis is done for a job than is needed, conserving bandwidth as well as processing and storage capacity. Critical colors also can be specified by the image designer, for example, further ensuring that the resultant image will be acceptable to the client.

Since any change in the amount of ink flow can affect the other measurement locations within the same ink key zone, a calculated correction can include any or all of the measurement locations within an ink key zone. Using the information from each of the measurement locations in that zone can allow an overall correction to be determined which minimizes the total color difference. A spectral-based closed loop control method can be used that calculates the ink key corrections for each inking unit, within each ink key zone. The method can minimize the spectral reflectance differences between the target reflectance spectra and the corresponding reflectance spectra measured at one or more locations within the ink key zone of interest. While the majority of printing uses four process colors, the control method is applicable to any number of colors. The control method can be similar to methods described in U.S. Patent Application Publication No. 2002/0104457, which is hereby incorporated by reference to provide background information relating to the present invention.

A simple linear equation can be applied to calculate such an inking correction. Although multi-color halftone image reproduction is in general a non-linear process, under certain conditions it is possible to use linear equations to model the process by restricting the range of the transformation to a sub-region of the color gamut. Within each sub-region having the target color as its origin, a set of “localized” equations can be used. The region over which the localized transformations will be linear can be dependent upon the target color location in color space, as well as the input and output variables used to represent the differences between the test and target areas in the transformation. For various locations in color space, it can be necessary to determine the range of film thicknesses over which an assumption of linearity holds. One such equation describes the relationship between the spectral reflectance values, at n selected wavelengths, and the corresponding solid ink density values that minimize the color-differences. A specific set of equations can be applied to each measurement location. A separate set of equations can be necessary for each measurement location since each measurement location can have a different sensitivity to changes in ink film thickness.

Once the target numbers and/or wavelengths are known, adjustments can be made due to knowledge of the printing characteristics of the system. For example, each press can reproduce input dot areas differently as well as exhibiting other variations, such that it is necessary to provide different ink control values to each machine in order to get a consistent output across machines. For instance, an input of 20% cyan on a first machine might actually result in an output of 23%, while the same 20% input might result on an output of 18% on a second machine. As such, it can be desirable to build a profile or “finger print” in order to provide an accessible record of the printing conditions of a particular press. Knowing how a press prints relative to what is input to the press allows the system to compensate for interpress variation, as the inputs can be adjusted for each machine based on knowledge of that machine. A library or database of information can be set up for each machine, and this information can be updated at periodic intervals or through intermittent or continual monitoring of the printing properties of the press. For instance, the behavior of any machine can change with each ink change, over time, after maintenance, according to the season, at each change of substrate stock, etc. The high speed rollers also can shift over time, which can change the size of the printed dots. Further, there may be at least one color, in a colorimetric color space, that varies more than the others during printing. It can be desirable to constantly evaluate all the inputs, assess the resultant output, change the fingerprint as necessary, and make the necessary adjustments to achieve the proper color.

As discussed above, it can be desirable to utilize a standard colormetric color space for intra-image color control. One industry standard colorspace for representing color is known as CIELAB colorspace, and specifies the location of a color in the colorspace by using three color vectors, including the lightness (L) and two vectors in the hue plane (AB), where the hue is defined by a two color coordinates in the hue plane and any hue can be defined by a point (A, B) in that two dimensional space defined by vector (A) and vector (B). For instance, a color having hue (5, 10) in the hue color plane and a lightness of (20) would have a CIELAB value of (20, 5, 10). It can be desirable to provide LAB values, as these are industry standard values that are used across the globe. A spectrophotometer does not measure in this three-dimensional space, but instead measures the entire visible spectrum to provide a continuous reflectance curve. While the spectrophotometer values can be used to determine necessary ink corrections, a conversion can be made to CIELAB values to be provided to the system operator so the operator can monitor the printing process using industry standards. If the color were to be measured using an RGB camera, for instance, there is no industry standard transform convert RGB values to CIELAB values, as RBG is not rich enough to define the true color gamut and transforms will not consistently produce the same results for every color.

There can be many other considerations when selecting and/or implementing a color control process. For printing systems that print numerous colors, for example, it can be necessary to determine realistic color tolerances for a large number and/or spectrum of colors. The tolerances also can differ between images and/or locations. For example, the visually acceptable color variations of a set of colors within a complex colorful picture can be significantly larger than those of the same set of colors contained in a low frequency (less complex) image. When determining an appropriate control algorithm, it also can be beneficial to quantify the amount of color variation that can be expected when no ink keys are moving for the most sensitive colors such as neutrals, skin tones, memory colors, browns, and pastels. Measurements made in the mid-tone to ¾tone regions can be most desirable for control. Since there is no guarantee that such locations will be available in an image, an algorithm can be generated to determine measurement locations for controlling an individual ink or multiple inks where only ½or ¼tone regions are available.

It can be difficult to control the printing press from measurement locations containing all four primary process colors, as the actual impact of the black ink can be difficult to determine since black ink mainly produces lightness changes that can otherwise be produced simply through changes in the CMY values. While existing systems can measure samples against a black measurement roller in accordance with CGATS and ISO standards, intra-image measurement system embodiments described herein can work with colorimetric targets derived from pre-press data. The measurement backing material can contribute significantly to the colorimetric measurement of the target, as a black backing as specified by the ISO standards for densitometric measurements can “bias” colorimetric measurements of the same target printed on certain substrate types. Any such bias may need to be considered in the equations for adjusting ink flows to “compensate” for the difference in the derived targets and the actual measured colorimetric values.

There also can be problems with inter-instrument color agreement. For example, target data can be acquired from ICC color profiles that may have been measured with low cost measuring instruments. The quality of the initial measuring instrument can have a large effect on inter-instrument agreement differences. It may be desirable to determine the agreement between the most commonly used and/or specific color measuring instruments for ICC color profiling and the instrument being used for printing. A library could be created that contains different adjustments for different ICC profiling instruments.

It is also possible to calculate ink layer thickness corrections, instead of solid ink density corrections, directly from spectral reflectance differences. Such a transformation can have distinct advantages for the control of non-process colors, process colors based on intra-image measurements only, and situations where only three-color neutral and black halftones test elements are available for control measurements, such as in newspaper printing. The elements for correction can depend upon several factors including the printing conditions such as the ink, substrate, and press being used, as well as the area coverage of the primary inks. As a result, correction can be done for each test area. Additionally, changes in the operating conditions of the press throughout a press run can have an influence on the print characteristics, such that the initial transformation can require updating throughout the printing process, or at least until the operating conditions have stabilized.

It should be recognized that a number of variations of the above-identified embodiments of the invention will be obvious to one of ordinary skill in the art in view of the foregoing description. Accordingly, the invention is not to be limited by those specific embodiments and methods of the present invention shown and described herein. Rather, the scope of the invention is to be defined by the following claims and their equivalents.

What is claimed is:

1. A method of intra-image color control in a web offset printing press, the method comprising:
capturing spectral reflectance data from a measurement area within a printed image on a substrate moving on the printing press;
utilizing the captured spectral reflectance data to determine if the color of the printed image within the measurement area is within a predefined color tolerance;
in the event that the color of the printed image within the measurement area is not within the predefined color tolerance, calculating a color adjustment; and
applying the calculated color adjustment to the printing press for color control.

2. A method of intra-image color control in a web offset printing press, the method comprising:
capturing spectral reflectance data from at least one measurement area within a printed image;
calculating a difference between the captured spectral reflectance data and target spectral reflectance data;
determining whether the difference exceeds a color tolerance;
calculating a color adjustment when the difference exceeds the color tolerance; and
applying the calculated color adjustment to the printing press for color control.

3. A method according to claim 2, and wherein:
the step of capturing spectral reflectance data includes capturing spectral reflectance data with a spectrophotometer.

4. A method according to claim 2, and wherein:
the measurement area is within an ink key zone.

5. A method according to claim 4, and wherein:
the step of applying the calculated color adjustment uses an ink key control mechanism for the ink key zone to adjust a corresponding ink key.

6. A method according to claim 2, and further comprising:
concurrently capturing image data while capturing spectral reflectance data, and analyzing the image data to ensure a positional accuracy of the at least one measurement area.

7. A method according to claim 2, and wherein:
none of the at least one measurement area must occur within a colorbar.

8. A method according to claim 2, and further comprising:
repeating the steps of claim 2 for each occurrence of the printed image on a moving web.

9. A method according to claim 2, and further comprising:
repeating the steps of claim 2 for the printed image at regular intervals on a moving web.

10. A method according to claim 2, and wherein:
the step of calculating a color adjustment includes using information about printing press characteristics to calculate a color adjustment that is accurate for that printing press.

11. A method of intra-image color control in a web offset printing press, the method comprising:
capturing spectral reflectance data from at least one measurement area in an ink key zone within a printed image;
converting the captured spectral reflectance values to colorimetric values;
comparing the colorimetric values to respective target colorimetric values to calculate a color difference value; and
calculating an inking correction using the captured spectral reflectance values when the color difference exceeds a color difference tolerance.

12. A method according to claim 11, and further comprising:
applying the color adjustment to an ink key control mechanism for the ink key zone.

13. A method according to claim 11, and wherein:
the step of capturing spectral reflectance data includes capturing spectral reflectance data with a spectrophotometer.

14. A method according to claim 11, and further comprising:
concurrently capturing image data while capturing spectral reflectance data, and analyzing the image data to ensure a positional accuracy of the at least one measurement area.

15. A method according to claim 11, and wherein:
none of the at least one measurement area must occur within a colorbar.

16. A method according to claim 11, and further comprising:
repeating the steps of claim 1 for the printed image at regular intervals on a moving web.

17. A system for intra-image color control in a web offset printing press, the system comprising:
an imaging system operable to capture spectral reflectance data from a measurement area within a printed image on a substrate moving on the printing press;
a data process device that utilizes the captured spectral reflectance data to determine if the color of the printed image within the measurement area is within a predefined color tolerance and, in the event that the color of the printed image within the measurement area is not within the predefined color tolerance, calculates a color adjustment signal that is utilized to control color of images printed on the moving substrate.

18. A system for intra-image color control in a web offset printing press, the system comprising:
a spectrophotometric imaging system operable to capture spectral reflectance data from a measurement area of an image printed on a moving web, the measurement area being within an ink key zone of the printing press; and
a data processing device containing instructions to calculate a difference between the captured spectral reflectance data and target spectral reflectance data, and to determine whether the calculated difference exceeds a color tolerance, the data processing device further containing instructions to calculate a color adjustment when the calculated difference exceeds the color tolerance and to supply a color adjustment signal to the printing press in response thereto.

19. A system according to claim 18, and further comprising:
an operator console for controlling the printing press.

20. A system according to claim 18, and further comprising:
an ink key control mechanism for the ink key zone operable to receive the color adjustment signal from the data processing device and to adjust a corresponding ink key in response thereto.

21. A system according to claim 18, and further comprising:
a display mechanism operable to receive the color adjustment signal from the data processing device and to display information about the color adjustment to a user, whereby the user can adjust a corresponding ink key in response thereto.

22. A system according to claim 18, and wherein:
the spectrophotometric imaging system is further operable to concurrently capture image data while capturing spectral reflectance data, and
the data processing device is further operable to analyze the image data to ensure a positional accuracy of the measurement area.

23. A system according to claim 18, and further comprising:
a database in communication with the data processing device, the database containing the target spectral reflectance data.

24. A system according to claim 23, and wherein:
the database further contains information about printing characteristics of the printing press that can be used to calculate the color adjustment.

25. A method of intra-image color control in a web offset printing press, the method comprising:
capturing spectral reflectance data from at least one measurement area within a printed image;
utilizing the captured spectral reflectance data to generate an ink density value representing the difference between an ink density value in the least one measurement area from which the spectral reflectance data was captured and a target ink density value for the at least one measurement area;
determining whether the ink density difference value exceeds a tolerance value; and
calculating a color adjustment when the ink density difference value exceeds the color tolerance; and
applying the calculated color adjustment to the printing press for color control.
